(19) United States
(12) Patent Application Publication
(10) Pub. No.: US 2013/0192310 A1
(43) Pub. Date: Aug. 1, 2013

(54) LASER ANNEALING APPARATUS

(71) Applicant: Atsushi NAKAMURA, Kanazawa-shi (JP)

(72) Inventor: Atsushi NAKAMURA, Kanazawa-shi (JP)

(21) Appl. No.: 13/747,831

(22) Filed: Jan. 23, 2013

(30) Foreign Application Priority Data
Jan. 27, 2012 (JP) 2012-015061

(51) Int. Cl. H01L 21/02

(52) U.S. Cl. CPC H01L 21/02686
USPC 65/157

(57) ABSTRACT

According to one embodiment, a laser annealing apparatus includes a laser device, an anneal chamber including a stage, a first housing, and an incidence window which is attached to the first housing, an optical module including a second housing and an emission window which is attached to the second housing, and a seal member which surrounds an optical path which connects a position where the emission window is attached and a position where the incidence window is attached, and effects sealing between the optical module and the anneal chamber, an inside of the seal member being an atmosphere of an inert gas.

### CROSS-REFERENCE TO RELATED APPLICATIONS

This application is based upon and claims the benefit of priority from Japanese Patent Application No. 2012-015061, filed Jan. 27, 2012, the entire contents of which are incorporated herein by reference.

### FIELD

Embodiments described herein relate generally to a laser annealing apparatus.

### BACKGROUND

Flat-panel display devices, such as liquid crystal display devices and electroluminescence display devices, have been used in various fields by virtue of their features. In such flat-panel display devices, a thin-film transistor (TFT) including a polysilicon semiconductor layer has begun to be used as a switching element of each of pixels.

This polysilicon semiconductor layer can be formed by an excimer laser anneal (ELA) method in which a laser beam is radiated in a pulsating form from an excimer laser device to amorphous silicon which is formed on an insulative substrate. In the excimer laser annealing method, it is required to stably form polysilicon over the entire area.

Since contamination on an optical path of a laser beam leads to a failure in obtaining a desired beam profile, periodical maintenance is indispensable.

### BRIEF DESCRIPTION OF THE DRAWINGS

FIG. 1 schematically illustrates the structure of a laser annealing apparatus according to an embodiment.

FIG. 2 schematically illustrates a state of a pulse laser beam which is shaped by a beam shaping module shown in FIG. 1.

### DETAILED DESCRIPTION

In general, according to one embodiment, a laser annealing apparatus includes: a laser device configured to emit a pulse laser beam; an anneal chamber including a stage on which a process substrate, on which an amorphous silicon thin film is formed, is placed, a first housing which surrounds the stage and an inside of which is an atmosphere of an inert gas, and an incidence window which is attached to the first housing and on which the pulse laser beam is made incident; and an optical module including a plurality of reflection mirrors and lenses which are disposed between the laser device and the anneal chamber, a second housing which surrounds the reflection mirrors and the lenses disposed between the laser device and the anneal chamber and an inside of which is an atmosphere of an inert gas, and an emission window which is attached to the second housing and from which the pulse laser beam is emitted toward the anneal chamber; and a seal member which surrounds an optical path which connects a position where the emission window is attached and a position where the incidence window is attached, and effects sealing between the optical module and the anneal chamber, an inside of the seal member being an atmosphere of an inert gas.

Embodiments will now be described in detail with reference to the accompanying drawings. In the drawings, structural elements having the same or similar functions are denoted by like reference numbers, and an overlapping description is omitted.

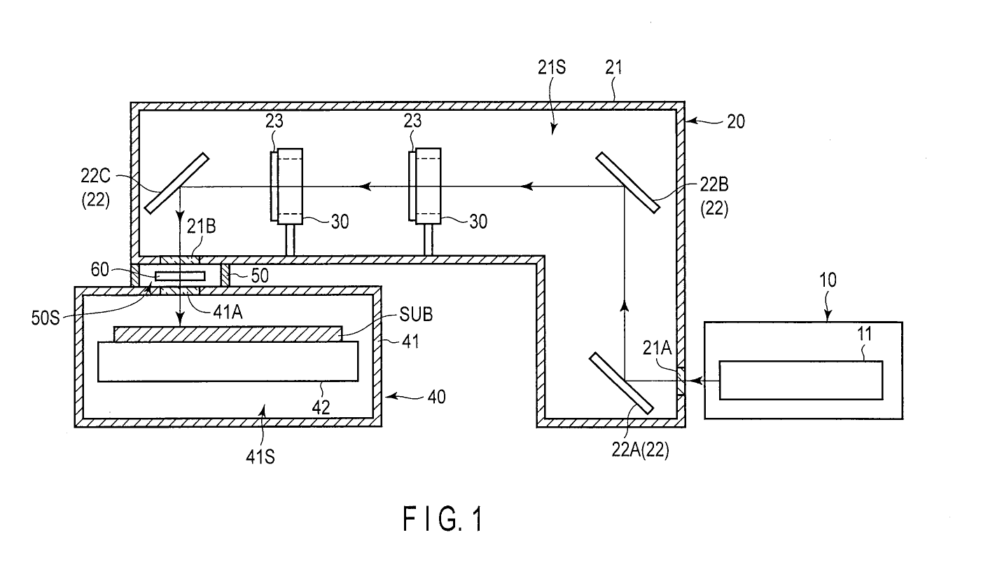

FIG. 1 schematically illustrates the structure of a laser annealing apparatus according to an embodiment.

Specifically, the laser annealing apparatus includes a laser device 10, an optical module 20, an anneal chamber 40, a seal member 50 and a beam shaping module 60.

The laser device 10 includes an excimer laser oscillator 11 which emits a pulse laser beam with an ultraviolet wavelength. The optical module 20 is disposed between the laser device 10 and the anneal chamber 40, and guides a pulse laser beam, which is emitted from the laser device 10, to the anneal chamber 40. The optical module 20 includes a housing 21, a plurality of reflection mirrors 22, a plurality of lenses 23, and lens holders 30.

The housing 21 is formed in a cylindrical shape surrounding an optical path between the laser device 10 and anneal chamber 40, and forms therein an airtight space 21S. An inert gas is introduced in the inner space 21S of the housing 21, and the inner space 21S is an inert gas atmosphere. It is desirable to use, for instance, inexpensive nitrogen gas (N₂) as the inert gas.

An incidence window 21A, on which the pulse laser beam emitted from the laser device 10 is made incident, is attached to that position of the housing 21, which is opposed to the laser device 10. An emission window 21B, from which the pulse laser beam is emitted toward the anneal chamber 40, is attached to that position of the housing 21, which is opposed to the anneal chamber 40. The incidence window 21A and emission window 21B are formed of, for instance, glass plates.

The reflection mirrors 22 mainly guide the pulse laser beam, which is emitted from the laser device 10, to the anneal chamber 40, and are fixed in the housing 21. The reflection mirrors 22 include, for example, a reflection mirror 22A configured to upwardly reflect the pulse laser beam which is taken in from the incidence window 21A, a reflection mirror 22B configured to deflect the optical path of the pulse laser beam reflected by the reflection mirror 22A, and a reflection mirror 22C configured to reflect the pulse laser beam, which has been reflected by the reflection mirror 22B, downward to the emission window 21B. It should be noted that the optical module 20 may include reflection mirrors 22 other than those shown in FIG. 1.

The lenses 23 are disposed along the optical path between the incidence window 21A and the emission window 21B, and impart predetermined optical characteristics to the pulse laser beam. The lenses 23 constitute a beam shaping optical system which shapes the pulse laser beam in a desired beam profile. For example, the pulse laser beam, which has passed through each lens 23, diverges, converges, or is collimated. The pulse laser beam, which has passed through the plural lenses 23, is shaped to have a desired beam profile, for example, a laterally elongated rectangular outer shape in a plane perpendicular to the direction of travel of the beam. It should be noted that the optical module 20 may include lenses 23 other than those shown in FIG. 1. The pulse laser beam, which is emitted from the emission window 21B via the beam shaping optical system, has the laterally elongated rectangular outer shape, and accordingly the emission window 21B also has a laterally elongated rectangular outer shape which is larger than the outer shape of the pulse laser beam.

The lens holders 30 hold the lenses 23 and are fixed within the housing 21. Although a detailed description of the structure of the lens holders 30 is omitted, each lens holder 30 includes a mechanism for adjusting the position of the lens 23 that is held.

A process substrate SUB, on which an amorphous silicon thin film is formed, is introduced into the anneal chamber 40. The anneal chamber 40 includes a housing 41 and a stage 42.

The housing 41 is formed in a box shape. Although not shown, a take-in port for introducing the process substrate SUB or a take-out port for taking out the process substrate SUB is formed in the housing 41. The housing 41 surrounds the stage 42 and forms therein an airtight space 41S. An inert gas, such as nitrogen gas (N₂), is introduced in the inner space 41S of the housing 41, and the inner space 41S is an inert gas atmosphere. The stage 42 is movable in two mutually perpendicular directions or in a rotational direction in a plane which is parallel to the process substrate SUB.

An incidence window 41A, on which the pulse laser beam emitted from the emission window 21B of the optical module 20 is made incident, is attached to that position of the housing 41, which is opposed to the optical module 20. The pulse laser beam, which is emitted from the emission window 21B of the optical module 20, has the laterally elongated rectangular outer shape, and accordingly the incidence window 41A also has a laterally elongated rectangular outer shape which is larger than the outer shape of the pulse laser beam. The incidence window 41A is formed of, for instance, a glass plate.

The seal member 50 surrounds an optical path which connects the position where the emission window 21B is attached and the position where the incidence window 41A is attached, effects sealing between the optical module 20 and the anneal chamber 40, and forms therein an airtight space 50S. An inert gas, such as nitrogen gas (N₂), is introduced in the inner space 50S formed by the seal member 50, and the inner space 50S is an inert gas atmosphere.

Thus, the emission window 21B and incidence window 41A are exposed to the inert gas, without being exposed to the outside air. Specifically, the inner surface of the emission window 21B is exposed to the inert gas in the inner space 21S of the optical module 20, and the outer surface of the emission window 21B is exposed to the inert gas in the inner space 50S of the seal member 50. Similarly, the inner surface of the incidence window 41A is exposed to the inert gas in the inner space 41S of the anneal chamber 40, and the outer surface of the incidence window 41A is exposed to the inert gas in the inner space 50S of the seal member 50.

The beam shaping module 60 shapes the pulse laser beam which is radiated on the process substrate SUB. The beam shaping module 60 is located between the optical module 20 and the anneal chamber 40, and is sealed by the seal member 50. To be more specific, the beam shaping module 60 is located on the optical path between the emission window 21B and incidence window 41A in the inner space 50S formed by the seal member 50. Thus, the beam shaping module 60 also is exposed to the inert gas, without being exposed to the outside air.

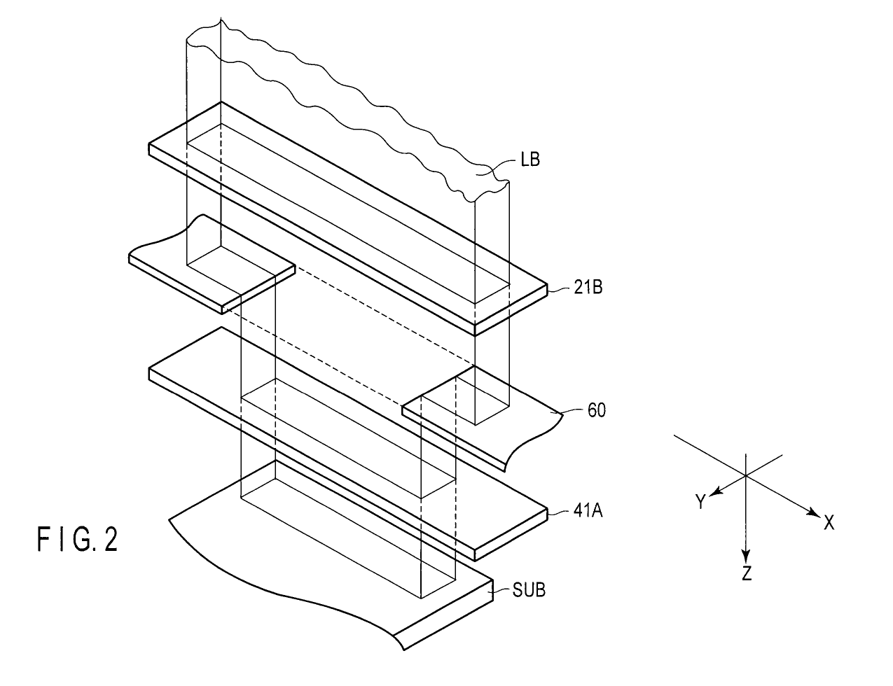

FIG. 2 schematically illustrates a state of a pulse laser beam LB which is shaped by the beam shaping module 60 shown in FIG. 1. It is assumed that the pulse laser beam LB forms a rectangular beam profile in a plane perpendicular to a beam travel direction Z of the pulse laser beam LB, and that a long-side direction of the rectangular beam profile is a first direction X and a short-side direction of the rectangular beam profile is a second direction Y.

Each of the emission window 21B and incidence window 41A has a pair of long sides along the first direction X, and a pair of short sides along the second direction Y. The length of each long side is greater than the length of the beam profile in the first direction X. In addition, the length of each short side is greater than the length of the beam profile in the second direction Y.

The beam shaping module 60 is configured to block, where necessary, part of the pulse laser beam LB emitted from the emission window 21B, in accordance with the outer dimensions of the process substrate SUB or the shape of that area of the process substrate SUB, which is to be irradiated with the pulse laser beam LB, and thereby narrows the beam profile of the pulse laser beam LB. The example illustrated corresponds to the case of restricting the length in the first direction X of the pulse laser beam LB which is emitted from the emission window 21B, and the beam shaping module 60 shields both end portions in the first direction X of the pulse laser beam LB. Although not illustrated, the beam shaping module 60 may be configured to restrict the length in the second direction Y of the pulse laser beam LB which is emitted from the emission window 21B. The pulse laser beam LB, which has passed through the beam shaping module 60, is incident on the incidence window 41A and is radiated on the process substrate SUB.

According to this laser annealing apparatus, the process substrate SUB, on which an amorphous silicon thin film has been formed, is placed on the stage 42 of the anneal chamber 40. After the stage 42 is moved and the position of the process substrate SUB is adjusted, a pulse laser beam which is set at a relatively high output is emitted from the laser device 10.

The pulse laser beam, which has been emitted from the laser device 10, travels through the optical module 20 and is so shaped as to have a desired beam profile. The shaped pulse laser beam is emitted from the emission window 21B to the outside of the optical module 20. The pulse laser beam, which has been emitted from the emission window 21B, travels through the beam shaping module 60 in the inner space 50S that is formed by the seal member 50, is ultimately shaped toward the process substrate SUB, and enters the anneal chamber 40 from the incidence window 41A. The pulse laser beam, which has been made incident from the incidence window 41A, is radiated on the process substrate SUB on the stage 42.

Thereby, the amorphous silicon is crystal-grown into polysilicon. Thereafter, the process substrate SUB, on which the polysilicon has been formed, is patterned in accordance with the shape of a thin-film transistor which is to be provided in each of pixels. Then, using the process substrate SUB, an array substrate for a flat-panel display device, such as a liquid crystal display device, is fabricated.

According to the present embodiment, the seal member 50 surrounds the optical path which connects the position where the emission window 21B is attached and the position where the incidence window 41A is attached, effects sealing between the optical module 20 and the anneal chamber 40, and the inside of the seal member is the inert gas atmosphere. Therefore, the outer surface of each of the emission window 21B and incidence window 41A is not exposed to the outside air.

In a structure in which the outer surface of each of the emission window 21B and incidence window 41A is exposed to the outside air, the pulse laser beam would react with a gas (e.g. ammonia gas) in the outside air, and fogging would occur on the outer surfaces of the emission window 21B and incidence window 41A, resulting in a failure in obtaining a desired beam profile. In such a structure, therefore, maintenance work, such as periodically removing these windows and cleaning them, is indispensable. In particular, when the window that is the glass plate is to be removed, since the window itself is long and heavy, there is a concern that the window is damaged or the window comes in contact with a nearby lens or reflection mirror, resulting in displacement of the optical axis. Consequently, the operation rate of the apparatus may possibly lower due to the maintenance work.

By contrast, in the present embodiment, since the outer surface of each of the emission window 21B and incidence window 41A is not exposed to the outside air, it is possible to suppress the occurrence of fogging on the outer surface of each of the emission window 21B and incidence window 41A. In addition, the inside of the optical module 20 and the inside of the anneal chamber 40 are inert gas atmospheres. Thus, the occurrence of fogging on the inner surface of each of the emission window 21B and incidence window 41A can be suppressed.

Thereby, periodical maintenance work is needless, and removal of windows, which requires careful work, is also needless. Therefore, it is possible to suppress a decrease in operation rate or a decrease in manufacturing yield. Besides, the load on workers who manage the apparatus can be reduced.

Moreover, according to the embodiment, the beam shaping module 60, which is located between the emission window 21B and incidence window 41A, is sealed by the seal member 50. Therefore, the beam shaping module 60 is not exposed to the outside air, and a reaction product between a gas in the outside air and the pulse laser beam can be prevented from adhering to the beam shaping module 60.

Furthermore, the space, in which the beam shaping module 60 is disposed, is separate from the inner space of the optical module 20 and the inner space of the anneal chamber 40, and is kept airtight. In other words, the space surrounded by the seal member 50 communicates with neither the space of the housing 21 nor the space of the housing 41. Therefore, even if particles occur due to the driving of the beam shaping module 60, such particles are prevented from flying into neighboring spaces.

In the meantime, the inside of the optical module 20, the inside of the anneal chamber 40 and the inside sealed by the seal member 50 are controlled at a low oxygen concentration by the introduction of inert gas, and the oxygen concentration is 100 ppm or less in each of these inside spaces.

As has been described above, according to the present embodiment, a laser annealing apparatus, which can suppress a decrease in manufacturing yield, can be provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A laser annealing apparatus comprising:
a laser device configured to emit a pulse laser beam;
an anneal chamber including a stage on which a process substrate, on which an amorphous silicon thin film is formed, is placed, a first housing which surrounds the stage and an inside of which is an atmosphere of an inert gas, and an incidence window which is attached to the first housing and on which the pulse laser beam is made incident;
an optical module including a plurality of reflection mirrors and lenses which are disposed between the laser device and the anneal chamber, a second housing which surrounds the reflection mirrors and the lenses disposed between the laser device and the anneal chamber and an inside of which is an atmosphere of an inert gas, and an emission window which is attached to the second housing and from which the pulse laser beam is emitted toward the anneal chamber; and
a seal member which surrounds an optical path which connects a position where the emission window is attached and a position where the incidence window is attached, and effects sealing between the optical module and the anneal chamber, an inside of the seal member being an atmosphere of an inert gas.

2. The laser annealing apparatus of claim 1, wherein the inert gas is nitrogen gas.

3. The laser annealing apparatus of claim 1, further comprising a beam shaping module which is located between the emission window and the incidence window, is sealed by the seal member, and shapes the pulse laser beam which is radiated on the process substrate.

4. The laser annealing apparatus of claim 1, wherein each of the incidence window and the emission window is a glass plate.

5. The laser annealing apparatus of claim 1, wherein an inner surface and an outer surface of the incidence window and an inner surface and an outer surface of the emission window are exposed to the inert gas.

6. The laser annealing apparatus of claim 1, wherein an oxygen concentration in each of the inside of the first housing, the inside of the second housing and the inside of a space sealed by the seal member is 1% or less.
